(19) United States
(12) Patent Application Publication
(10) Pub. No.: US 2016/0013159 A1
(43) Pub. Date: Jan. 14, 2016

(54) CHIP, CHIP-STACKED PACKAGE USING THE SAME, AND METHOD OF MANUFACTURING THE CHIP-STACKED PACKAGE

(71) Applicant: Jong-oh KWON, Suwon-si (KR)

(72) Inventor: Jong-oh KWON, Suwon-si (KR)

(21) Appl. No.: 14/755,422

(22) Filed: Jun. 30, 2015

(30) Foreign Application Priority Data
Jul. 8, 2014 (KR) 10-2014-0085360

(51) Int. Cl. H01L 25/065; H01L 23/48; H01L 23/498; H01L 29/04; H01L 23/00

(52) U.S. Cl. CPC H01L 25/0657; H01L 29/045; H01L 24/05; H01L 23/49838; H01L 23/48; H01L 2224/04042; H01L 2224/05023; H01L 2224/48227; H01L 2224/48108; H01L 2225/0651; H01L 2225/06568; H01L 2924/10156; H01L 2924/10253

(57) ABSTRACT

A chip including a chip body, the chip body including a surface portion and edges surrounding the surface portion, at least one of the edges having a sloped portion, and a side pad on the sloped portion may be provided. A chip-stacked package including a bonding pad on a top surface thereof, a chip on the wiring substrate, the chip including edges and a side pad on the sloped portion, at least one of the edges having a sloped portion, and a conductive line electrically connecting the bonding pad of the wiring substrate to the side pad of the sloped portion may be provided.

### CROSS-REFERENCE TO RELATED APPLICATION

This application claims priority under 35 U.S.C. §119 to Korean Patent Application No. 10-2014-0085360, filed on Jul. 8, 2014, in the Korean Intellectual Property Office, the disclosure of which is incorporated herein in its entirety by reference.

### BACKGROUND

The inventive concepts relate to chips, packages using the same, and/or methods of manufacturing the package, and more particularly, to chips, chip-stacked packages using the same, and/or methods of manufacturing the chip-stacked package.

In the semiconductor industry, chip packages including a chip that is multi-functional and has a compact design and higher capacity have been developed. Accordingly, a chip-stacked package in which a plurality of chips are stacked on a circuit board has been suggested. In particular, a chip that can achieve the foregoing demands (e.g., multi-function, compact design, higher capacity) with respect to the chip-stacked package is being developed. Further, methods of aligning stacked chips and methods of electrically connecting the stacked chips such that the foregoing demands are achieved with respect to the chip-stacked package.

### SUMMARY

The inventive concepts provide chips including a side pad that may be easily applied to a chip-stacked package.

The inventive concepts also provide chip-stacked packages that are miniaturized using chips, at least one of which includes side pads on at least one sloped edge thereof, wherein the side pads of the chips stacked are connected to each other using a conductive line.

The inventive concepts also provide methods of manufacturing a chip-stacked package using chips, at least one of which includes side pads on at least one sloped edge thereof.

According to an example embodiment, a chip includes a chip body including at least one sloped portion at one or more edges of the chip body, and a side pad on the at least one sloped portion.

According to some example embodiments, the chip body may have a quadrangular shape, and each of two facing ones from among the edges may have the sloped portion.

According to some example embodiments, the chip body may have a quadrangular shape, and a respective one of the edges may have the sloped portion.

According to some example embodiments, the chip body may have a quadrangular shape, and at least one from among the edges has a vertical portion, which is perpendicular to a top surface of the chip body.

According to some example embodiments, each of two facing ones from among the edges may have the sloped portion, and each of the other two facing ones from among the edges may have the vertical portion.

According to some example embodiments, the sloped portion may have an inclination angle of a range between about 90° and about 180° with respect to the surface portion of the chip body.

According to some example embodiments, the sloped portion may have an inclination angle of a range between about 120° and about 150° with respect to the surface portion of the chip body.

According to some example embodiments, the side pad may be spaced apart by a first distance along the sloped portion from a top surface of the chip body and may be spaced apart by a second distance along the sloped portion from a bottom surface of the chip body.

According to some example embodiments, the chip may further include an insulating layer on the sloped portion, the insulating layer being around the side pad.

According to some example embodiments, the sloped portion may be a crystal plane of the chip body that has substantially no crystal defects.

According to some example embodiments, the chip body may be a silicon wafer and the chip body may have a top surface with a (100) plane and the sloped portion with a (111) plane or a (110) plane.

According to some example embodiments, the chip body may be a silicon wafer and the chip body may have a top surface with a (110) plane and the sloped portion with a (111) plane or a (100) plane.

According to an example embodiment, a chip-stacked package include a wiring substrate including a bonding pad on a top surface thereof, a chip on the wiring substrate, the chip including edges and a side pad on the sloped portion, at least one of the edges having a sloped portion, and a conductive line electrically connecting the bonding pad of the wiring substrate to the side pad of the sloped portion.

According to some example embodiments, the chip-stacked package may further include an insulating layer on the sloped portion, the insulating layer being around the side pad and between the conductive line and the sloped portion.

According to some example embodiments, the chip may be a controller chip or a memory chip.

According to some example embodiments, each of two facing ones from among the edges may have the sloped portion.

According to some example embodiments, each of two facing ones from among the edges may have the sloped portion, and each of the other two facing ones from among the edges has a vertical portion, which is perpendicular to a top surface of the chip body.

According to some example embodiments, the wiring substrate may include a plurality of the bonding pads including the bonding pad, the chip may include a plurality of the side pads including the side pad, the plurality of the side pads corresponding to the plurality of bonding pads, respectively, and at least some of the plurality of bonding pads may be connected to at least some of the plurality of side pads, respectively, through a plurality of the conductive lines including the conductive line.

According to an example embodiment, a chip-stacked package includes a first chip including a first chip body, the first chip body including a first sloped portion at at least one edge of the first chip body and a first side pad on the first sloped portion, a second chip on the first chip, the second chip including a second chip body, the second chip body including a second sloped portion on at least one edge of the second chip body and a second side pad on the second sloped portion, and a conductive line on the first sloped portion and the second sloped portion, the conductive line electrically connecting the first side pad of the first chip and the second side pad of the second chip.

According to some example embodiments, the first sloped portion and the second sloped portion may be configured to be on a same plane when seen from above.

According to some example embodiments, the first chip may be a controller chip and the second chip may be a memory chip.

According to some example embodiments, the chip-stacked package may further include a plurality of the first side pads including the first side pad, a plurality of the second side pads including a second side pad and corresponding to the plurality of first side pads, respectively, and at least some of the plurality of first side pads are connected to at least some of the plurality of second side pads, respectively, through the plurality of the conductive lines including the conductive line.

According to some example embodiments, a size of the second chip may be less than a size of the first chip, and the second chip may be stacked on the first chip such that the second chip is entirely within a boundary of the first chip when seen from above.

According to some example embodiments, a size of the second chip may be same as a size of the first chip, and the second chip may be stacked on the first chip to have an offset with respect to the first chip.

According to an example embodiment, a chip-stacked package may include a wiring substrate including a bonding pad on a top surface thereof, a first chip on the wiring substrate, the first chip including a first chip body, the first chip body including a first sloped portion at at least one edge of the first chip body, and a first side pad on the first sloped portion, a second chip on the first chip, the second chip including a second chip body, the second chip body including a second sloped portion at at least one edge of the second chip body, and a second side pad on the second sloped portion, and a conductive line electrically connecting the bonding pad to at least one selected from the first side pad of the first chip and the second side pad of the second chip.

According to some example embodiments, the conductive line may be on the wiring substrate, the first sloped portion, and the second sloped portion such that the bonding pad is connected to the at least one selected from the first side pad and the second side pad.

According to some example embodiments, the conductive line may be on the wiring substrate, the first sloped portion, a surface of the first chip, and the second sloped portion such that the bonding pad is connected to the first side pad and the second side pad.

According to some example embodiments, the chip-stacked package may further include a plurality of the first side pads including the first side pad, a plurality of the second side pads including the second side pad and corresponding to the plurality of first side pads, respectively, and at least some of the plurality of first side pads are connected to at least some of the plurality of second side pads, respectively, through a plurality of the conductive lines.

According to some example embodiments, the chip-stacked package may further include an encapsulation member on the wiring substrate and encapsulating the first chip and the second chip, and an external connection terminal at a bottom surface of the wiring substrate.

According to some example embodiments, the first and second sloped portions may be on any one of two facing ones from among the edges of the first and second chip bodies and first and second vertical portions, which are perpendicular to respective surfaces of the first and second chip bodies, may be on the other one of two facing ones from among the edges of the first and second chip bodies.

According to some example embodiments, a size of the second chip may be same as a size of the first chip, and the second chip may be stacked on the first chip to have an offset with respect to the first chip.

According to an example embodiment, a chip-stacked package includes a wiring substrate including ponding pads on a top surface thereof, a first chip on the wiring substrate, the first chip including a first chip body, a first sloped portion at at least one edge of the first chip body, and first side pads on the first sloped portion, a second chip on the first chip, the second chip including a second chip body, a second sloped portion at at least one edge of the second chip body, and surface pads on a top surface of the second chip body, and a first conductive line electrically connecting the bonding pads to the surface pads of the second chip.

According to some example embodiments, the chip-stacked package may further include a second conductive line electrically connecting the bonding pads to the first side pads of the first chip.

According to an example embodiment, a method of manufacturing a chip-stacked package may include providing a wafer including a plurality of chips, each of the plurality of chips including a chip body, the chip body including a planar portion at a center of the chip body and edge portions at edges of the chip body, forming a sloped portion on at least one of the edges of one of the plurality of chips by wet-etching the edge portions at the edges of the chip body, forming a side pad on the sloped portion, separating the plurality of chips by grinding a rear surface of the wafer such that each of the plurality of chips including the side pad on the sloped portion, aligning and stacking the plurality of chips, each including the sloped portion, with respect to each other on a wiring substrate that comprises a bonding pad, and forming a conductive line connecting the bonding pad to the side pad.

According to some example embodiments, the forming a sloped portion may include forming a mask layer on the central portion of the chip body to expose the edge portion of the chip body, and wet-etching the edge portion of the chip body by using the mask layer as an etching mask.

According to some example embodiments, the forming a sloped portion may include wet-etching the edge portion of the chip body such that the sloped portion of the chip is formed according to an etching rate difference between crystal planes of the wafer.

According to some example embodiments, the forming a sloped portion may include forming the slope portion to have a crystal plane having substantially no defect.

According to some example embodiments, the aligning and stacking the plurality of chips may include stacking the plurality of chips such that the sloped portions of the plurality of chips constitute a same plane.

According to some example embodiments, the forming a conductive line may include forming the conductive line by printing a conductive paste.

According to an example embodiment, a chip-stacked package include a wiring substrate having bonding pads thereon, a first chip on the wiring substrate and including a first chip body, the first chip body including a first planar top surface, and first edges surrounding the first planar top surface, at least one of the first edges being a first sloped edge, first side pads on the first sloped edge, and first conductive lines electrically connecting the bonding pads to the first side pads, respectively.

According to some example embodiments, the chip-stacked package may further include a second chip on the first chip and including a second chip body, the second chip body including a second planar top surface, and second edges surrounding the second planar top surface, at least one of the second edges being a second sloped edge, second side pads on the second sloped edge, and second conductive lines electrically connecting the bonding pads to the second side pads, respectively.

According to some example embodiments, the second conductive lines may electrically connect the bonding pads to the second side pads via the first side pads.

According to some example embodiments, the first sloped edge and the second sloped edge are one a same plane when seen from above.

According to some example embodiments, the chip-stacked package may further include a second chip on the first chip and including a second chip body, the second chip body including a second planar top surface and vertical edges surrounding the second planar top surface, the vertical edges being perpendicular to the second top planar surface, surface pads on the second planar top surface sloped edge, and second conductive lines electrically connecting the bonding pads to the surface pads, respectively.

According to some example embodiments, the second conductive lines may electrically connect the bonding pads to the surface pads via the first side pads.

According to some example embodiments, the first chip body may have a quadrangular shape, and at least one of the first edges may be a vertical edge, which is perpendicular to the first planar top surface.

According to some example embodiments, the first chip body may be a silicon wafer, and when the first planar top surface has a (100) crystal plane and the first sloped edge may have a (111) crystal plane or a (110) plane, and when the first planar top surface has a (110) crystal plane and the first sloped edge may have a (111) crystal plane or a (100) plane.

### BRIEF DESCRIPTION OF THE DRAWINGS

Example embodiments of the inventive concepts will be more clearly understood from the following detailed description taken in conjunction with the accompanying drawings in which:

FIGS. 1A and 1B are plan and cross-sectional views of the chip illustrating parts of a chip according to an example embodiment of the inventive concepts, respectively;

FIG. 2 is a partial cross-sectional view for explaining a sloped portion according to an example embodiment of the inventive concepts;

FIG. 3 is a partial cross-sectional view for explaining the sloped portion according to another example embodiment of the inventive concepts;

FIGS. 4 and 5 are plan views illustrating parts of chips according to other example embodiments of the inventive concepts;

FIG. 6 is a cross-sectional view of the chips of FIGS. 4 and 5;

FIG. 7 is a plan view illustrating parts of a chip according to another example embodiment of the inventive concepts;

FIG. 8 is a cross-sectional view of the chip of FIG. 7;

FIG. 9 is a plan view illustrating parts of a chip-stacked package according to an example embodiment of the inventive concepts;

FIG. 10 is a cross-sectional view of the chip of FIG. 9;

FIGS. 11 and 12 are cross-sectional views for explaining conductive lines and a method of forming the conductive lines of FIGS. 9 and 10;

FIG. 13 is a cross-sectional view illustrating a state where the conductive lines are formed on an insulating layer and side pads of the sloped portion as shown in FIG. 3;

FIG. 14 is a plan view illustrating parts of a chip-stacked package according to another example embodiment of the inventive concepts;

FIG. 15 is a cross-sectional view of the chip-stacked package of FIG. 14;

FIG. 16 is a plan view illustrating parts of a chip-stacked package according to another example embodiment of the inventive concepts;

FIG. 17 is a cross-sectional view of the chip-stacked package of FIG. 16;

FIG. 18 is a plan view illustrating parts of a chip-stacked package according to another example embodiment of the inventive concepts;

FIG. 19 is a cross-sectional view of the chip-stacked package of FIG. 18;

FIG. 20 is a plan view illustrating parts of a chip-stacked package according to another example embodiment of the inventive concepts;

FIG. 21 is a cross-sectional view of the chip-stacked package of FIG. 20;

FIG. 22 is a plan view illustrating parts of a chip-stacked package according to another example embodiment of the inventive concepts;

FIG. 23 is a cross-sectional view of the chip-stacked package of FIG. 22;

FIG. 24 is a plan view illustrating parts of a chip-stacked package according to another example embodiment of the inventive concepts;

FIG. 25 is a cross-sectional view of the chip-stacked package of FIG. 24;

FIGS. 26 and 27 are cross-sectional views illustrating chip-stacked packages according to other example embodiments of the inventive concepts;

FIGS. 28 through 36 are cross-sectional views for explaining a method of manufacturing a chip-stacked package, according to an example embodiment of the inventive concepts;

FIGS. 37 and 38 are perspective view for explaining a method of forming a sloped portion of FIG. 29;

FIG. 39 is a block diagram illustrating elements of a chip-stacked package according to an example embodiment of the inventive concepts;

FIG. 40 is a block illustrating an electronic system including a chip-stacked package, according to an example embodiment of the inventive concepts;

FIG. 41 is a perspective view illustrating an electronic device to which a chip-stacked package is applied, according to an example embodiment of the inventive concepts; and

FIG. 42 is a block diagram illustrating elements of a card using a chip-stacked semiconductor package, according to an example embodiment of the inventive concepts.

### DETAILED DESCRIPTION OF EXAMPLE EMBODIMENTS

As used herein, the term “and/or” includes any and all combinations of one or more of the associated listed items. Expressions such as “at least one of,” when preceding a list of elements, modify the entire list of elements and do not modify the individual elements of the list.

The inventive concepts will now be described more fully with reference to the accompanying drawings, in which example embodiments of the inventive concepts are shown.

The inventive concepts will now be described more fully with reference to the accompanying drawings, in which example embodiments of the inventive concepts are shown. The inventive concepts may, however, be embodied in many different forms and should not be construed as being limited to the example embodiments set forth herein; rather these example embodiments are provided so that this disclosure will be thorough and complete, and will fully convey the concept of the inventive concepts to one of ordinary skill in the art. Also, thicknesses or sizes of layers in the drawings are exaggerated for convenience of explanation and clarity.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items. Like reference numerals denote like elements throughout.

It will be understood that, although the terms first, second, third etc. may be used herein to describe various members, components, regions, layers, and/or sections, these members, components, regions, layers, and/or sections should not be limited by these terms. These terms are only used to distinguish one member, component, region, layer, or section from another member, component, region, layer, or section. Thus, a first member, component, region, layer, or section discussed below could be termed a second member, component, region, layer, or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to schematic illustrations of the example embodiments. As such, variations from the shapes of the illustrations as a result, for example, of manufacturing techniques and/or tolerances, are to be expected. Thus, the example embodiments should not be construed as limited to the particular shapes of regions illustrated herein but may be to include deviations in shapes that result, for example, from manufacturing. Embodiments of the inventive concepts may be individually realized, or also may be realized by being combined with one or more other example embodiments.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Hereinafter, some example embodiments will be explained in further detail with reference to the accompanying drawings.

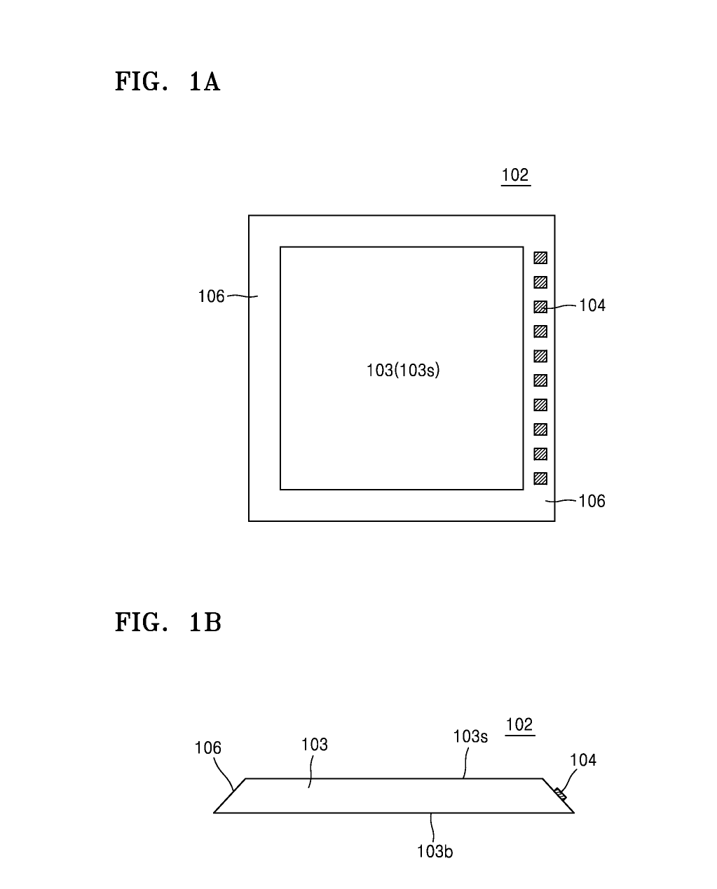

FIGS. 1A and 1B are plan and cross-sectional views of a chip illustrating parts of a chip according to an example embodiment of the inventive concepts.

A chip 102 includes a chip body 103. The chip 102 may be a memory chip. The memory chip may be a volatile memory chip, for example, a dynamic random-access memory (DRAM) or a static random-access memory (SRAM) or a nonvolatile memory chip such as a phase-change random-access memory (PRAM), a magnetoresistive random-access memory (MRAM), a ferroelectric random-access memory (FeRAM), or a resistive random-access memory (RRAM). An integrated circuit (IC) may be formed on the chip body 103. The chip body 103 may be formed by forming an IC on a silicon wafer. The chip body 103 may have a quadrangular shape. A sloped portion 106 is formed on at least one edge of the chip body 103.

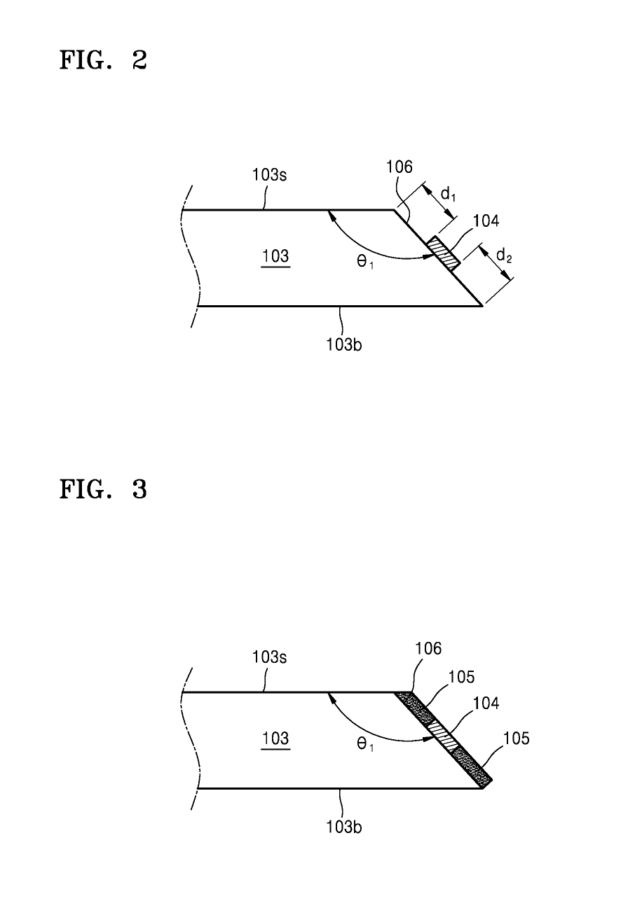

Although the sloped portion 106 is formed on each of all of the edges of FIG. 1, the present example embodiments are not limited thereto and the sloped portion 106 may be formed on each of two facing edges. The sloped portion 106 may be formed on each of two facing edges from among the edges as illustrated in FIG. 2.

The sloped portion 106 that extends from a top surface 103s of the chip body 103 to a bottom surface 103b may be formed to be inclined. The sloped portion 106 may be formed due to a wet-etching rate difference between crystal planes of the chip body 103. The chip body 103 may be a silicon wafer having a (100) plane, and the sloped portion 106 may have a (111) plane or a (110) plane. The chip body 103 may be a silicon wafer having a (110) face, and the sloped portion 106 may have a (111) plane or a (100) plane.

Because the sloped portion 106 may be formed by using wet-etching, the sloped portion 106 may be a crystal plane having substantially no crystal defect. Because the sloped portion 106 is a crystal plane having substantially no defect, conductive lines may be formed on the sloped portion 106 by using a printing method. A method of forming the sloped portion 106 will be explained below in detail.

Side pads 104 are formed on the sloped portion 106. The side pads 104 may be metal pads, for example, copper, nickel, stainless steel, or beryllium copper pads. The number of the side pads may be one or more. The side pads 104 may be elements for electrical connection with, for example, a wiring substrate or another chip.

When the chip 102 including the side pads 104 that are formed on the sloped portion 106 is used, a chip-stacked package may be easily realized as will be described below and the chip-stacked package may be multi-functional and have a compact design and high capacity.

FIG. 2 is a partial cross-sectional view for explaining a sloped portion according to an example embodiment of the inventive concepts. FIG. 3 is a partial cross-sectional view for explaining the sloped portion according to another example embodiment of the inventive concepts.

As shown in FIGS. 2 and 3, a sloped portion 106 that extends from the top surface 103s of the chip body 103 to the bottom surface 103b is formed to be inclined. The sloped portion 106 may have an inclination angle θ1 of a range between about 90° and about 180° with respect to the top surface 103s of the chip body 103. The sloped portion 106 may have the inclination angle θ1 of a range between about 120° and about 150° with respect to the top surface 103s of the chip body 103.

The side pads 104 may be spaced apart by a first distance d1 along the sloped portion 106 from the top surface 103s of the chip body 103 and may be spaced apart by a second distance d2 along the sloped portion 106 from the bottom surface 103b of the chip body 103. As illustrated in FIG. 3, an insulating layer 105 may be formed on the sloped portion 106 around the side pads 104. The insulating layer 105 may be formed in order to insulate the side pads 104 from a peripheral member. The insulating layer 105 may be, for example, an oxide layer or a nitride layer.

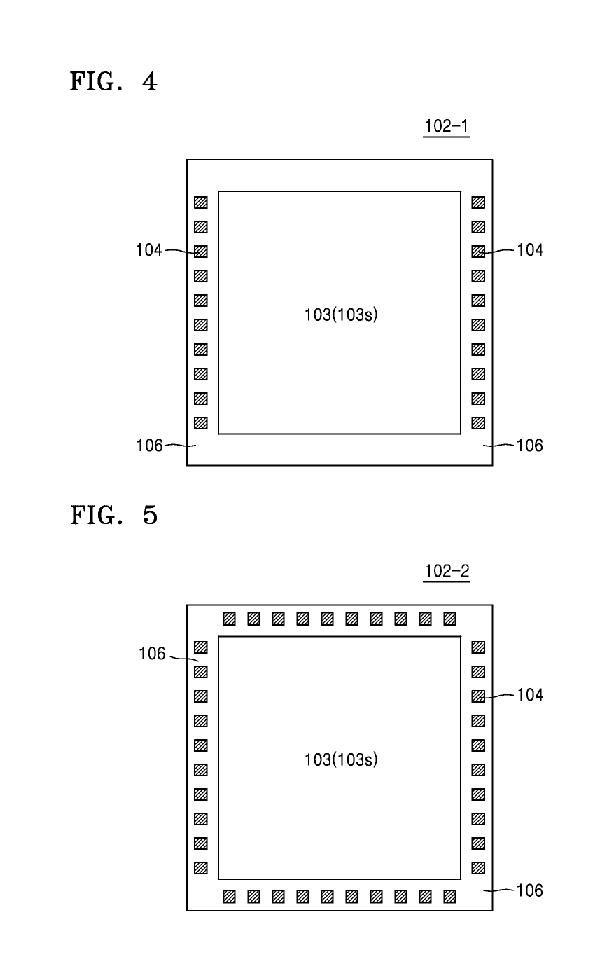

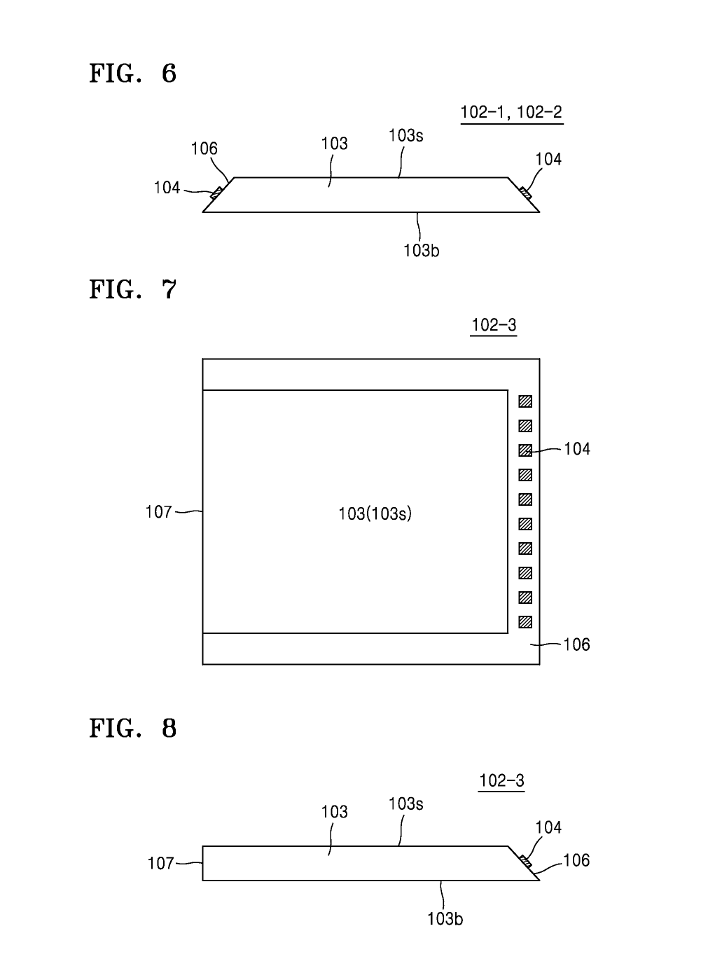

FIGS. 4 and 5 are plan views illustrating parts of chips according to other example embodiments of the inventive concepts. FIG. 6 is a cross-sectional view of the chips of FIGS. 4 and 5.

A chip 102-1 of FIG. 4 may be the same as the chip 102 of FIGS. 1A and 1B except that side pads 104 are formed on sloped portions 106 that are located on two facing edges from among four edges.

A chip 102-2 of FIG. 5 may be the same as the chip 102 of FIGS. 1A and 1B except that side pads 104 are formed on sloped portions 106 at all of the four edges. When the chips 102-1 and 102-2 are applied to a chip-stacked package, various degrees of freedom in design may be obtained.

FIG. 7 is a plan view illustrating parts of a chip according to another example embodiment of the inventive concepts. FIG. 8 is a cross-sectional view of the chip of FIG. 7.

A chip 102-3 of FIGS. 7 and 8 may be the same as the chip 102 of FIGS. 1A and 1B except that the sloped portions 106 are formed on three edges from among four edges and a vertical portion 107 that is perpendicular to the top surface 103s of the chip body 103 is formed on the remaining edge.

In the chip 102-3 of FIGS. 7 and 8, the sloped portion 106 may be formed on one of two facing edges and the vertical portion 107 that is perpendicular to the surface 103a of the chip body 103 may be formed on the other of the two facing edges. Although the vertical portion 107 is formed on one edge of the chip body 103 of FIGS. 7 and 8, the vertical portion 107 may be formed on each of three edges excluding the sloped portion 106.

The side pads 104 may be formed on any one of the sloped portions 106 of the chip 102-3 of FIGS. 7 and 8. When the chip 102-3 is applied to a chip-stacked package, various degrees of freedom in design may be obtained.

Example embodiments in which various chip-stacked packages including the above chips are realized will now be explained in detail. Various chip-stacked packages are realized by using a chip that includes sloped portions that are formed on at least one edge and side pads that are formed on any one of the sloped portions. The following chip-stacked packages are examples and the technical scope of the inventive concepts is not limited thereto.

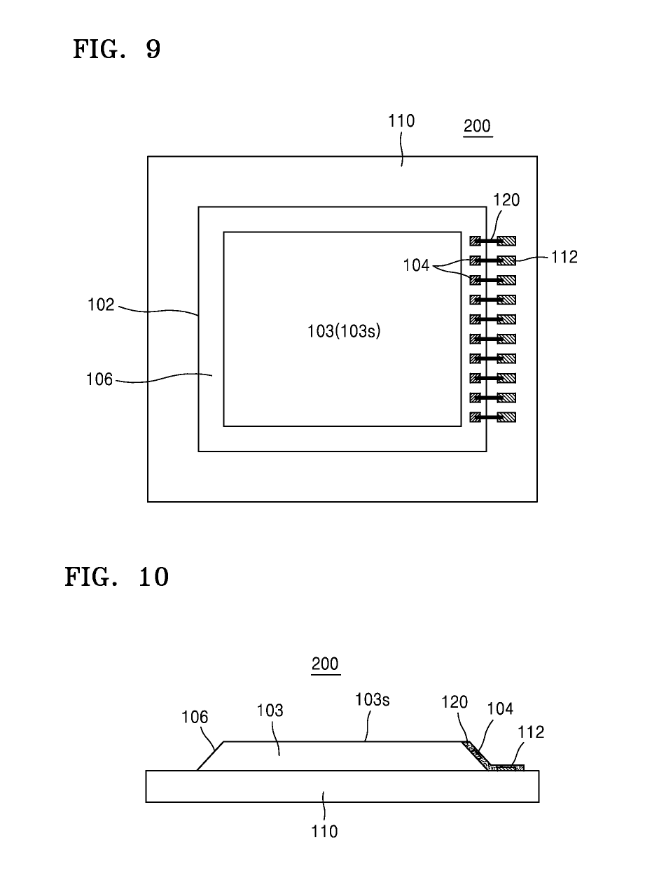

FIG. 9 is a plan view illustrating parts of a chip-stacked package according to an example embodiment of the inventive concepts. FIG. 10 is a cross-sectional view of the chip-stacked package of FIG. 9.

A chip-stacked package 200 may include a wiring substrate 110 on a top surface of which bonding pads 112 are disposed. The plurality of bonding pads 112 may be provided. The wiring substrate 110 may be a printed circuit board (PCB). Various chips, for example, the chips 102, 102-1, 102-2, or 102-3 of FIGS. 1 through 8, may be stacked on the wiring substrate 110. Only the chip 102 of FIGS. 1A and 1B is stacked in FIG. 9 for convenience of explanation. For example, the chip 102 may be a controller chip or a memory chip.

As described above, the chip 102 may include the chip body 103, the sloped portion 106 that is formed on at least one edge of the chip body 103, and the side pads 104 that are formed on the sloped portion 106. The sloped portion 106 may be a crystal plane of the chip body 103 that has substantially no crystal defect. The sloped portion 106 may be formed on each of two facing edges from among the edges of the chip body 103. Further, as described with reference to FIG. 8, the vertical portion 107 may be formed on one of the two facing edges of the chip body 103, while the sloped portion 106 is formed on the other of the two facing edges of the chip body 103. The plurality of side pads 104 may be provided to correspond to the plurality of bonding pads 112, respectively.

Conductive lines 120 may be formed on the wiring substrate 110 and the sloped portion 106 to electrically connect the bonding pads 112 to the side pads 104. All of the bonding pads 112 and the side pads 104 that correspond to each other may be connected to each other through the conductive lines 120. The conductive lines 120 may be metal wires that are formed by, for example, printing a conductive paste. The conductive lines 120 may be metal wires, for example, copper or tungsten aluminum wires. Widths of the conductive lines 120 may be equal to or less than 10 micrometers (μm), that is, several micrometers. A method of forming the conductive lines 120 will be explained below in detail.

Because the chip-stacked package 200 constructed as described above is realized by using the chip 102 including the sloped portion 106, which is formed on at least one edge, and the side pads 104 formed on the sloped portion 106, the conductive lines 120 may easily provide a connection between the chip 102 and the wiring substrate 110 by using a printing method.

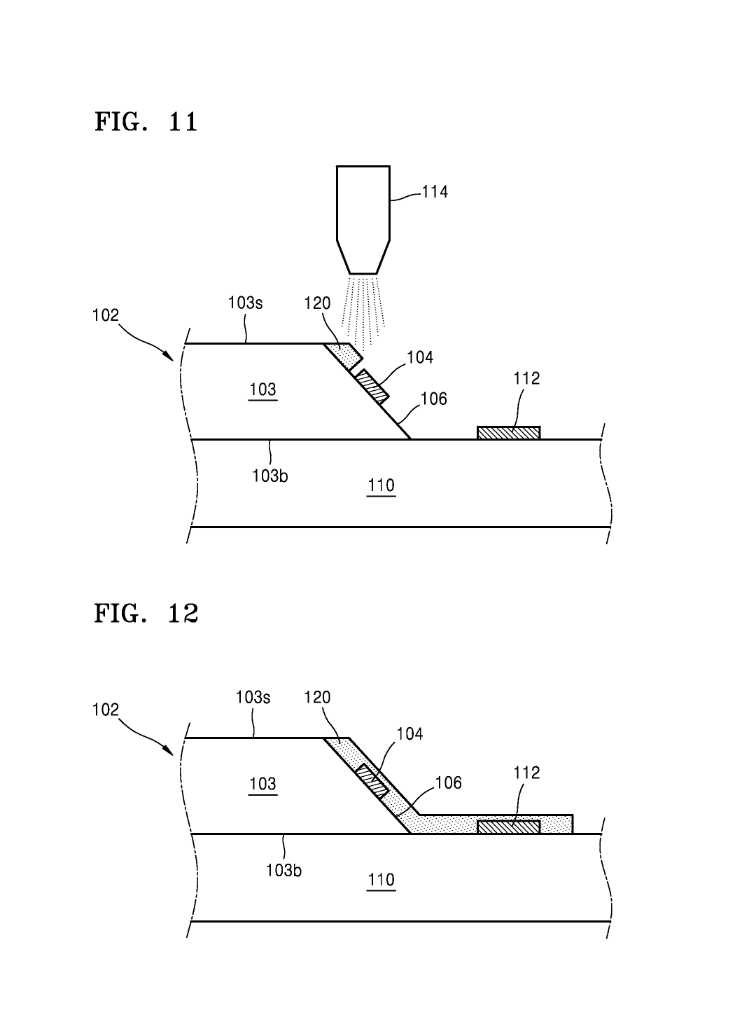

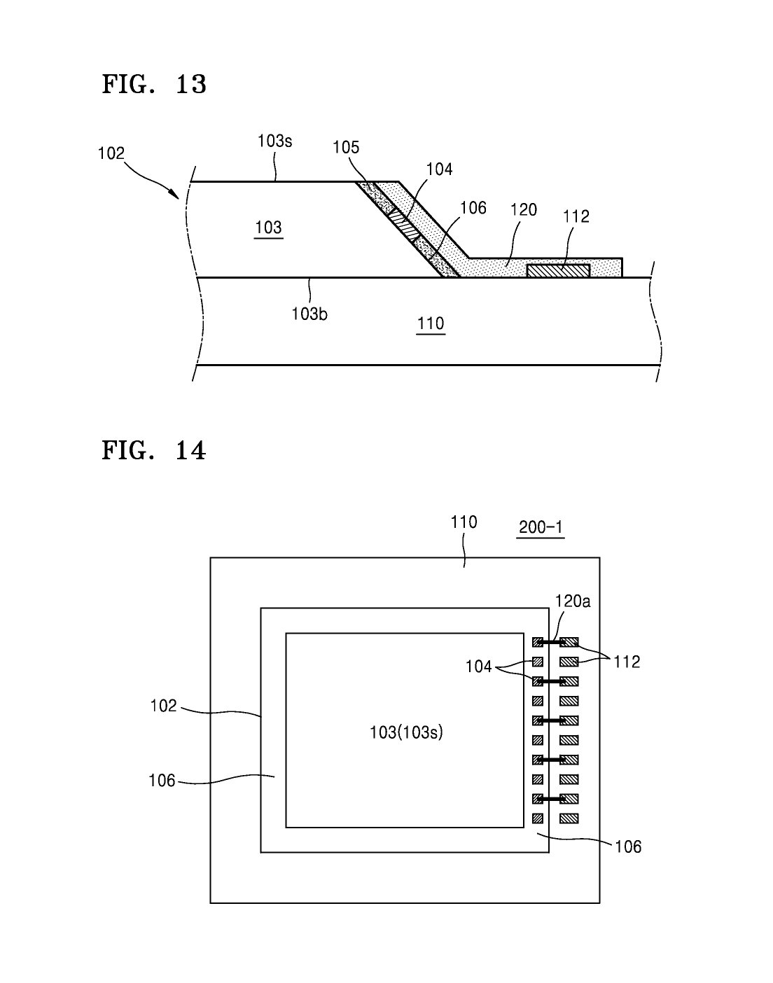

FIGS. 11 and 12 are cross-sectional views for explaining the conductive lines and a method of forming the conductive lines of FIGS. 9 and 10. FIG. 13 is a cross-sectional view illustrating a state where the conductive lines are formed on the insulating layer and the side pads on the sloped portion 106, as shown in FIG. 3.

As described above with reference to FIGS. 9 and 10, the conductive lines 120 may be formed by using a printing device 114 on the sloped portion 106 of the chip body 103. The conductive lines 120 may be formed by being printed along the sloped portion 106 from the top surface 103s of the chip body 103 toward the bottom surface 103b of the chip body 103. The printing device 114 may be, for example, a silk screen printing device, an inkjet printing device, or a nano-imprint device. The conductive lines 120 may be formed by printing a conductive paste obtained by mixing a conductive material, for example, conductive particles (metal or carbon particles) with a solvent on the sloped portion 106 and the wiring substrate 110. The conductive lines 120 may be formed as a metal layer, for example, a copper layer, an aluminum layer, or a tungsten layer. Because the sloped portion 106 is a crystal plane of the chip body 103 that has substantially no crystal defect, the conductive lines 120 may be formed by a printing method using the printing device 114. When the printing device 114 is used, the conductive lines 120 may be formed by using a printing method to have widths equal to or less than 10 μm, that is, several μm.

In FIG. 13, an insulating layer 105 and the side pads 104 may be formed on the sloped portion 106 of FIG. 3 and the conductive lines 120 may be formed on the insulating layer 105 and the side pads 104. The insulating layer 105 may be formed on the sloped portion 106 to be disposed between the conductive lines 120 and the sloped portion 106. When the conductive lines 120 are formed on the insulating layer 105 as shown in FIG. 14, insulating characteristics between the side pads 104 and an external member may be improved.

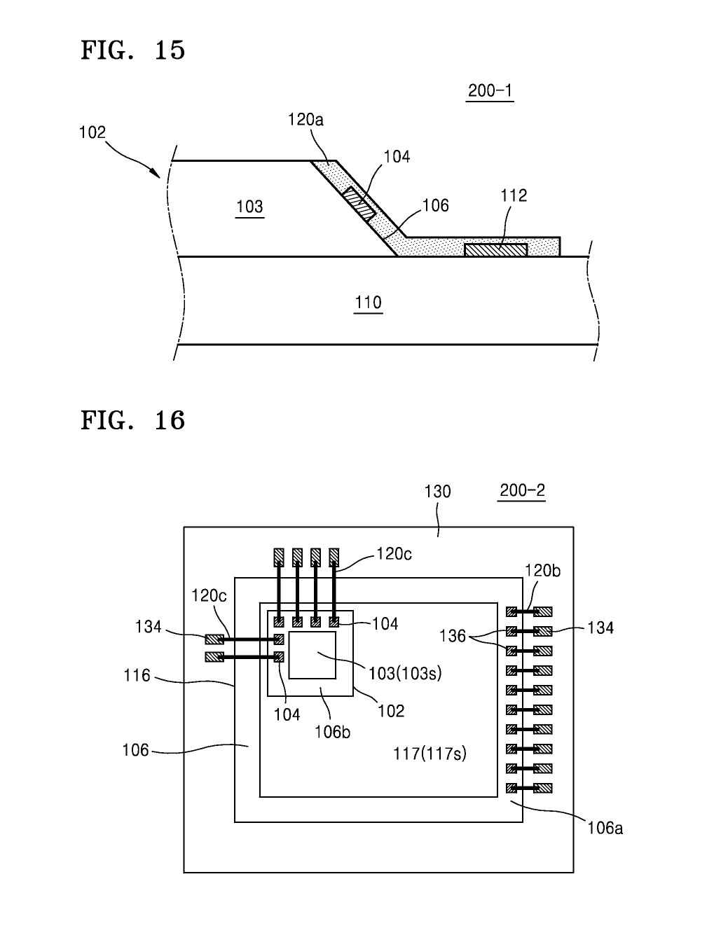

FIG. 14 is a plan view illustrating elements of a chip-stacked package according to another example embodiment of the inventive concepts. FIG. 16 is a cross-sectional view of the chip-stacked package of FIG. 15.

A chip-stacked package 200-1 may be the same as the chip-stacked package 200 of FIGS. 9 and 10 except that all of the bonding pads 112 and the side pads 104 are not connected to each other through conductive lines 120a.

The chip-stacked package 200-1 may include the wiring substrate 110 having the plurality of bonding pads 112 on a top surface thereof and the chip 102 stacked on the wiring substrate 110. The chip 102 may include the plurality of side pads 104 formed on the sloped portion 106, which is located at at least one edge of the chip body 103. The side pads 104 are arranged to respectively correspond to the plurality of bonding pads 112.

The conductive lines 120a are formed on the wiring substrate 110 and the sloped portion 106 such that the bonding pads 112 are electrically connected to the side pads 104. For example, some of the bonding pads 112 and the side pads 104 corresponding to each other may be connected to each other through the conductive lines 120a. In the chip-stacked package 200-1 constructed as described above, the conductive lines 120a may connect the chip 102 to the wiring substrate 110 using the side pads 104 formed on the slope portion 106 of the chip 102.

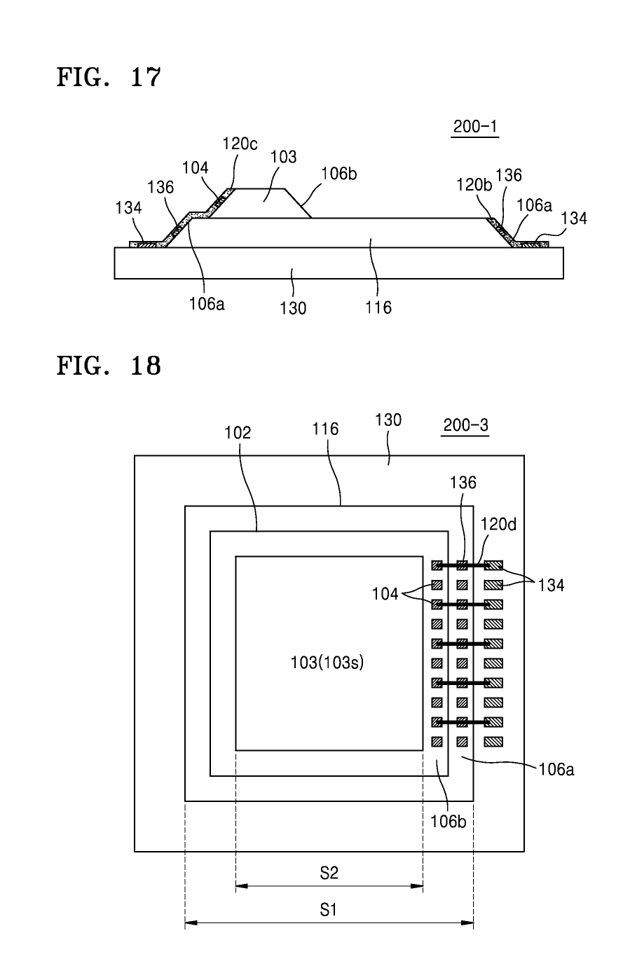

FIG. 16 is a plan view illustrating parts of a chip-stacked package according to another example embodiment of the inventive concepts. FIG. 17 is a cross-sectional view of the chip-stacked package of FIG. 16.

A chip-stacked package 200-2 may be the same as the chip-stacked packages 200 and 200-1 of FIGS. 9, 10, 14, and 15 except that a plurality of chips are stacked on a wiring substrate 130 and the plurality of chips and conductive lines 120b and 120c are variously connected to each other. Although two chips, e.g., a first chip 116 and the second chip 102 (hereinafter, referred to as a second chip), are stacked in the chip-stacked package 200-2 of FIGS. 17 and 18, the present example embodiments are not limited thereto and more chips may be stacked.

The chip-stacked package 200-2 may include the wiring substrate 130 on a top surface of which bonding pads 134 are disposed. The wiring substrate 130 may be, for example, a PCB. The first chip 116 may be stacked on the wiring substrate 130. The first chip 116 may be the same as any of the various chips 102, 102-1, 102-2, and 102-3 of FIGS. 1 through 8. Reference numeral 116 for denoting the first chip is selected to distinguish it from the second chip 102. The first chip 116 may be, for example, a controller chip.

The first chip 116 may include a first chip body 117, a first sloped portion 106a formed at at least one edge of the first chip body 117, and first side pads 136 formed on the first sloped portion 106a. The first sloped portion 106a may be formed on each of two facing edges from among edges of the first chip body 117. As described above with reference to FIG. 8, the vertical portion 107 may be formed on, for example, any one of the two facing edges of the first chip body 117.

The second chip 102 is stacked on a top surface 117s of the first chip body 117. The second chip 102 may be, for example, a memory chip. The second chip 102 may be the same as any of the chips 102, 102-1, and 102-3 of FIGS. 1 through 8. The second chip 102 may be smaller than the first chip 116 in terms of area. Accordingly, the second chip 102 may be stacked inside the first chip body 117 when seen from the above.

The second chip 102 may include the chip body 103 (hereinafter, referred to as a second chip body), the sloped portion 106 (hereinafter, referred to as a second slopped portion) formed at at least one edge of the second chip body 103, and the side pads 104 (hereinafter, referred to as second side pads) formed on the second sloped portion 106. The second sloped portion 106 may be formed on, for example, each of two facing edges from among edges of the second chip body 103. As described above with reference to FIG. 8, the vertical portion 107 (see FIG. 9) may be formed on, for example, any one of the two facing edges of the second chip body 103.

The first sloped portion 106a of the first chip 116 and the second sloped portion 106b of the second chip 102 may not be on the same plane. That is, the second sloped portion 106b of the second chip 102 may be formed to be inside than the first sloped portion 106a of the first chip 116.

The first side pads 136 of the first chip 116 may be electrically connected to the bonding pads 134 through first conductive lines 120b, which are formed on the wiring substrate 130 and the first sloped portion 106a. The first chip 116 and the second chip 102 may be electrically connected to each other by connecting the first side pads 136 of the first chip 116 to the second side pads 104 of the second chip 102 through second conductive lines 120c, which are formed on the first sloped portion 106a, the top surface 117s of the first chip 116, and the second sloped portion 106.

Also, the first chip 116, the second chip 102, and the wiring substrate 130 may be electrically connected to each other by connecting the bonding pads 134, the first side pads 136 of the first chip 116, and the second side pads 104 of the second chip 102 with each other through the second conductive lines 120c, which are formed on the wiring substrate 130, the first sloped portion 106a, and the second sloped portion 106. The first and second conductive lines 120b and 120c may be, for example, metal wires, which are formed by printing a conductive paste.

In the chip-stacked package 200-2 constructed as described above, the first and second chips 116 and 102 and the wiring substrate 130 may be easily connected through the first and second conductive lines 120b and 120c and by using the first and second chips 116 and 102 including the first and second sloped portions 106a and 106b respectively having the first and second side pads 136 and 104. The chip-stacked package 200-2 may be multi-functional and/or have high capacity by stacking the first and second chips 116 and 102. The chip-stacked page 200-2 may have a smaller size than one in which surface pads are provided on a flat top surface of chip bodies. The chip-stacked page 200-2 may have a smaller size because the chip-stacked package 200-2 uses the first and second chips 116 and 102, which include the first and second sloped portions 106a and 106b on which the first and second side pads 136 and 104 are respectively formed.

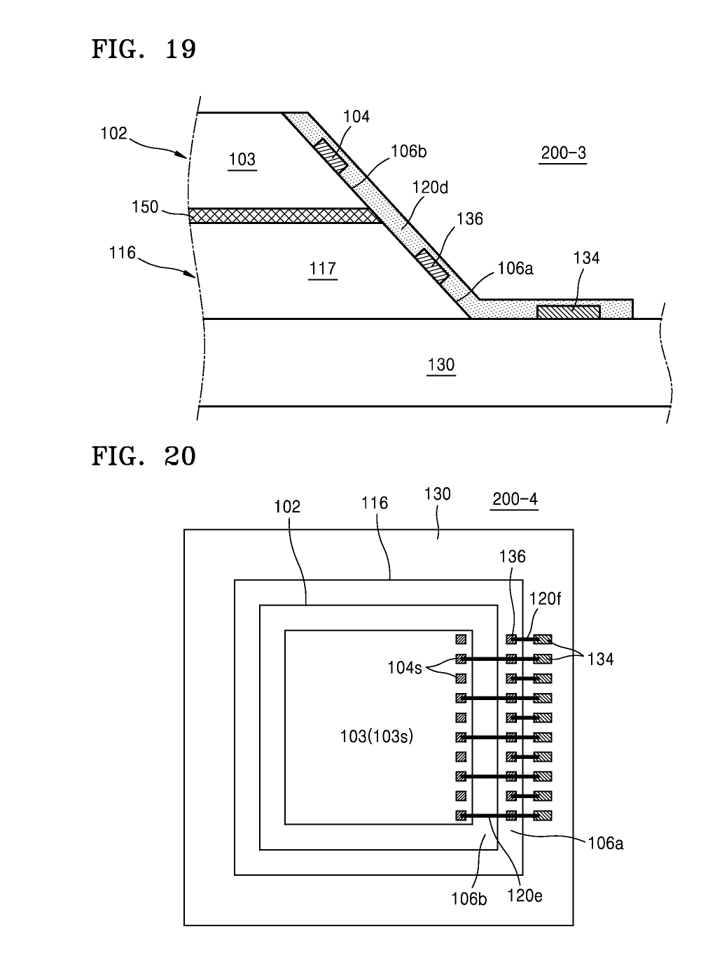

FIG. 18 is a plan view illustrating parts of a chip-stacked package according to another example embodiment of the inventive concepts. FIG. 19 is a cross-sectional view of the chip-stacked package of FIG. 18.

A chip-stacked package 200-3 may be the same as the chip-stacked package 200-2 of FIGS. 16 and 17 except for an arrangement of the bonding pads 134, a size of the second chip 102, and an electrical connection between the bonding pads 134 and the first and second side pads 136 and 104.

The chip-stacked package 200-3 may include the wiring substrate 130 including the bonding pads 134 and the first chip 116 stacked on the wiring substrate 130. The first chip 116 may have a size (or a width) S1. As described above with reference to FIGS. 16 and 17, the first chip 116 may include the first chip body 117, the first sloped portion 106a, and the first side pads 136. The first side pads 136 may be arranged to correspond to the plurality of bonding pads 134.

The second chip 102 may be stacked on the top surface 117s of the first chip body 117. An adhesive layer 150, for example, an adhesive tape, may be disposed between the first chip body 117 and the second chip 102. The second chip 102 may be the same as any of the chips 102, 102-1, 102-2, and 102-3 of FIGS. 1 through 8. The second chip 102 may have a size (or a width) S2 that is less than the size S1. The second chip 102 may be larger than the second chips 102 in FIGS. 16 and 17. The second chip 102 of FIGS. 18 and 19 may be entirely stacked on and within the top surface 117s of the first chip body 117 when seen from the above.

The second chip 102 may include the second chip body 103, the second sloped portion 106 formed at at least one edge of the second chip body 103, and the second side pads 104 formed on the second sloped portion 106b. The second sloped portion 106b may be formed on each of two facing edges from among edges of the second chip body 103. The second side pads 104 may be arranged to correspond to the plurality of bonding pads 134.

The first sloped portion 106a of the first chip 116 and the second sloped portion 106b of the second chip 102 of FIGS. 18 and 19 may be on the same plane. That is, the first sloped portion 106a and the second sloped portion 106b may be on the same plane when seen from above. The first side pads 136 of the first chip 116 may be electrically connected to the second side pads 104 of the second chip 102 through conductive lines 120d, which are formed on the first sloped portion 106a and the second sloped portion 106.

The first chip 116 and the second chip 102, and the bonding pads 134 of the wiring substrate 130 may be connected to each other through the conductive lines 120d, which are formed on the wiring substrate 130, the first sloped portion 106a, and the second sloped portion 106. As shown in FIGS. 18 and 19, some of the bonding pads 134 and the side pads 104 may be connected to each other through the conductive lines 120d. The conductive lines 120d may be metal wires that are formed by, for example, printing a conductive paste. The conductive lines 120d may be more finely formed by using a printing method when the first sloped portion 106a and the second sloped portion 106b are on the same plane.

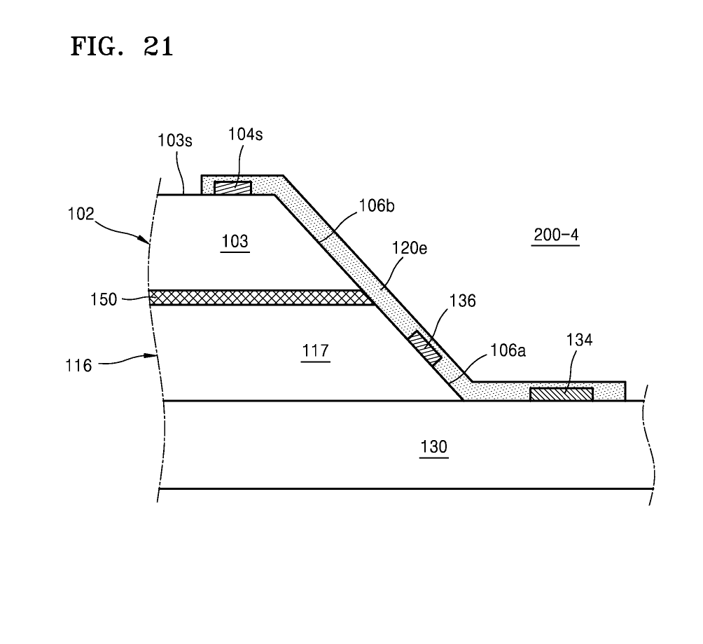

FIG. 20 is a plan view illustrating essential parts of a chip-stacked package according to another example embodiment of the inventive concepts. FIG. 21 is a cross-sectional view of the chip-stacked package of FIG. 21.

A chip-stacked package 200-4 may be the same as the chip-stacked package 200-2 of FIGS. 18 and 19 except for a shape of the second chip 102 and an electrical connection between the bonding pads 134 and the first side pads 136.

The chip-stacked package 200-4 may include the wiring substrate 130 including the plurality of bonding pads 134 and the first chip 116 stacked on the wiring substrate 130. The first chip 116 may include the first chip body 117, the first sloped portion 106a, and the first side pads 136 as described above with reference to FIGS. 18 and 19. The first side pads 136 may be arranged to correspond to the plurality of bonding pads 134.

The second chip 102 is stacked on the top surface 117s of the first chip body 117. The second chip 102 may be the same as any of the various chips 102, 102-1, 102-2, and 102-3 of FIGS. 1 through 8 except that the second side pads 104 are not formed.

The second chip 102 may include the second chip body 103 and the second sloped portion 106b formed at at least one edge of the second chip body 103. The second sloped portion 106b may be formed on each of two facing edges from among edges of the second chip body 103. Further, surface pads 104s may be arranged on the top surface 103s of the second chip body 103 to correspond to the bonding pads 134.

As shown in FIG. 21, the first sloped portion 106a of the first chip 116 and the second sloped portion 106b of the second chip 102 may be on the same plane. That is, the first sloped portion 106a and the second sloped portion 106b may be on the same plane when seen from above.

The first side pads 136 of the first chip 116 and the surface pads 104s of the second chip 102 may be electrically connected to each other through first conductive lines 120e, which are formed on the first sloped portion 106a and the second sloped portion 106b. The first chip 116 and the second chip 102 may be connected to the bonding pads 134 through the conductive lines 120e that are formed on the wiring substrate 130, the first sloped portion 106a, and the second sloped portion 106b.

Some of the bonding pads 134 and the surface pads 104s may be connected to each other through the first conductive lines 120e. The conductive lines 120e may be metal wires that are formed by, for example, printing a conductive paste. The first conductive lines 120e may be more finely formed by using a printing method when the first sloped portion 106a and the second sloped portion 106b are on the same plane.

The first side pads 136 of the first chip 116 and the bonding pads 134 may be electrically connected to each other through second conductive lines 120f, which are formed on the wiring substrate 130 and the second sloped portion 106.

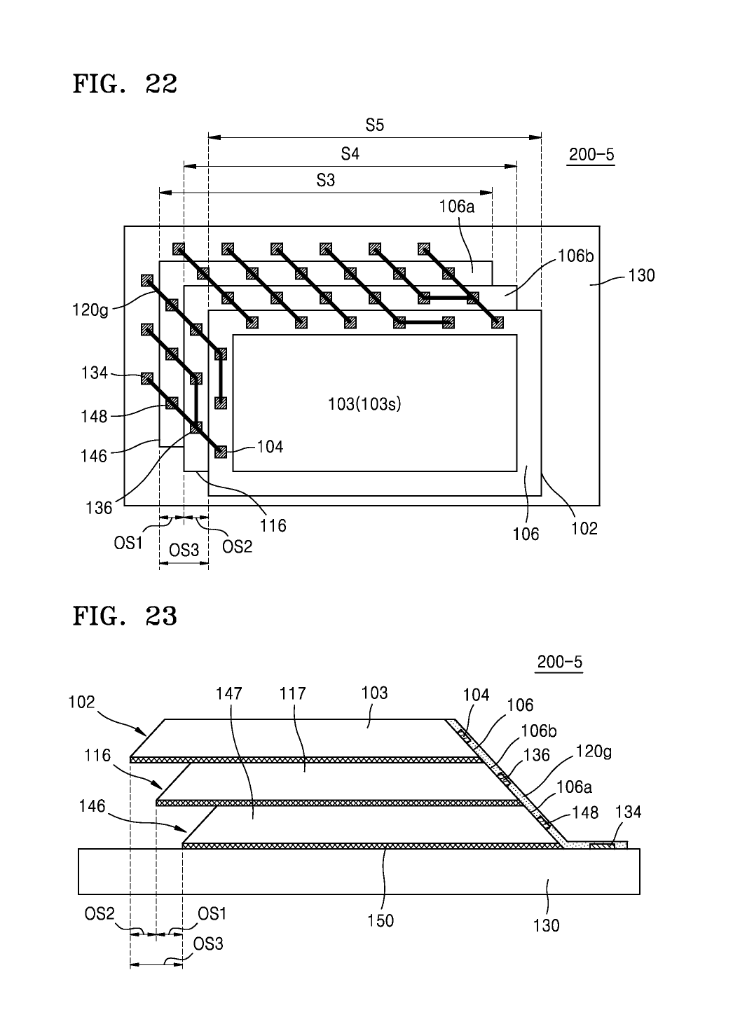

FIG. 22 is a plan view illustrating essential parts of a chip-stacked package according to another example embodiment of the inventive concepts. FIG. 23 is a cross-sectional view of the chip-stacked package of FIG. 22.

A chip-stacked package 200-5 may be the same as any of the chip-stacked packages 200-2, 200-3, and 200-4 of FIGS. 16, 18, and 20 except that a plurality of chips having the same size are stacked on the wiring substrate 130 to have an offset. Although three chips, e.g., a first chip 146, a second chip 116 and a third chip 102 are stacked in the chip-stacked package 200-5 of FIGS. 22 and 23, more chips may be stacked.

The chip-stacked package 200-5 includes the wiring substrate 130, on a top surface of which the bonding pads 134 are disposed, and the first chip 146 stacked on the wiring substrate 130. The first chip 146 may be the same as any of the various chips 102, 102-1, 102-2, and 102-3 of FIGS. 1 through 8. The first chip 146 may have a size (or a width) S3.

The first chip 146 may include a first chip body 147, a first sloped portion 106a formed at at least one edge of the first chip body 147, and first side pads 148 formed on the first sloped portion 106a. The first sloped portion 106b may be formed on, for example, each of two facing edges from among edges of the first chip body 147. The first chip 146 may be, for example, a memory chip or a controller chip.

The second chip 116 may be stacked on the first chip 146 with the adhesive layer 150 therebetween. For example, the second chip 116 may have a size (or a width) S4 that is the same as the size S3. That is, the first chip 146 and the second chip 116 may have the same size. The second chip 116 may be stacked on the first chip body 147 to have a first offset OS1. An edge of the second chip 116, which is stacked on the first chip 146 to have the first offset OS1, may be spaced apart or protrude from an edge of the first chip 146.

The second chip 116 may include a first chip body 117, a second sloped portion 106b formed at at least one edge of the second chip body 117, and second side pads 136 formed on the second sloped portion 106b. The second sloped portion 106b may be formed on, for example, each of two facing edges from among edges of the second chip body 117. The second chip 116 may be, for example, a memory chip or a controller chip.

The third chip 102 may be stacked on the second chip 116 with the adhesive layer 150 therebetween. For example, the third chip 102 may have a size (or a width) S5 that is the same as the sizes S3 and S4. The second chip 116 and the third chip 102 may have the same size. The third chip 102 may be stacked on the second chip body 117 to have a second offset OS2. An edge of the third chip 102, which is stacked on the second chip 116 to have the second offset OS2, may be spaced apart or protrude from an edge of the second chip 116. Accordingly, the third chip 102, which is stacked on the second chip 116 to have a third offset OS3, may be spaced apart or protrude from an edge of the first chip 146.

The third chip 102 may include a third chip body 103, a third sloped portion 106c formed at at least one edge of the third chip body 103, and third side pads 104 formed on the third sloped portion 106c. The third sloped portion 106c may be formed on, for example, each of two facing edges from among edges of the third chip body 103. The third chip 116 may be, for example, a memory chip or a controller chip.

The first sloped portion 106a of the first chip 146, the second sloped portion 106b of the second chip 116, and the third sloped portion 106c of the third chip 102 may be on the same plane when seen from the above. The first chip 146, the second chip 116, and the third chip 102 may be connected to the bonding pads 134 and the first through third side pads 148, 136, and 104 through conductive lines 120g, which are formed on the wiring substrate 130, the first sloped portion 106a, the second sloped portion 106b, and the third sloped portion 106c. The conductive lines 120g may be more finely formed by using, for example, a printing method when the first sloped portion 106a, the second sloped portion 106b, and the third sloped portion 106c are on the same plane when seen from the above.

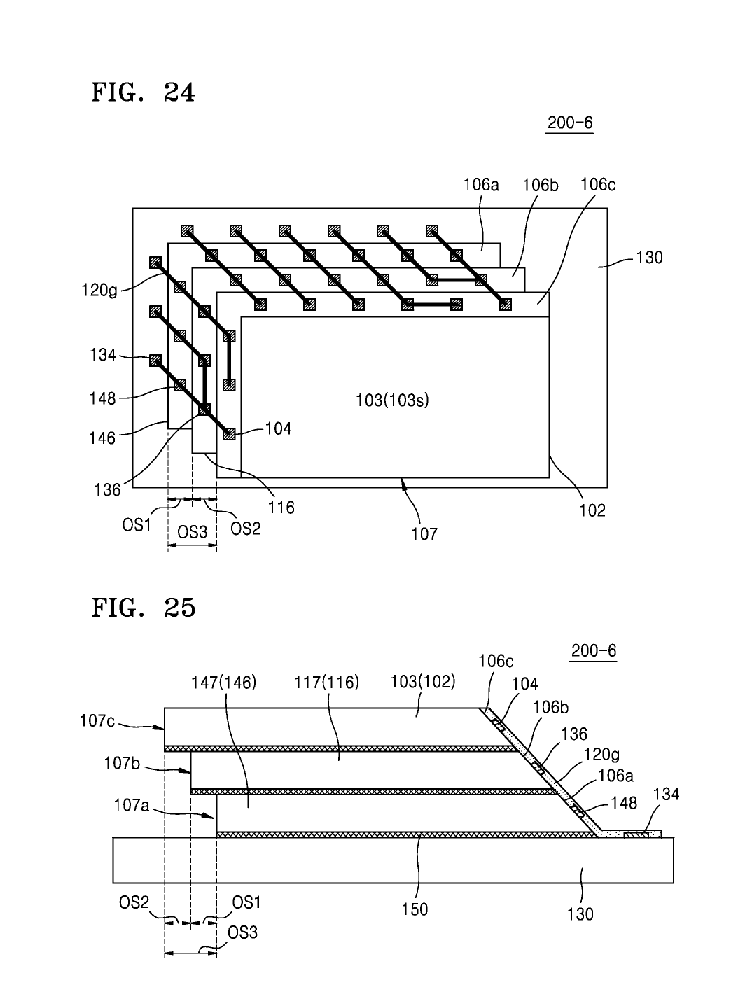

FIG. 24 is a plan view illustrating parts of a chip-stacked package according to another example embodiment of the inventive concepts. FIG. 25 is a cross-sectional view of the chip-stacked package of FIG. 24.

A chip-stacked package 200-6 may be the same as the chip-stacked package 200-5 of FIGS. 22 and 23 except that first through third vertical portions 107a, 107b, and 107c are formed on respective edges of the first through third chips 146, 116, and 102.

The chip-stacked package 200-6 includes the wiring substrate 130 and the first chip 146 that is stacked on the wiring substrate 130, like the chip-stacked package 200-5 of FIGS. 22 and 23. The first vertical portion 107a may be formed on an edge of the first chip body 147. The first sloped portion 106a may be formed on, for example, any one of two facing edges from among edges of the first chip body 147 and the first vertical portion 107a that is perpendicular to a top surface of the first chip body 147 may be formed on the other of the two facing edges from among edges of the first chip body 147.

The second chip 116 may be stacked on the first chip 146 to have the first offset OS1. The second vertical portion 107b may be formed on an edge of the second chip body 117 of the second chip 116, like in the first chip 146. The third chip 102 may be stacked on the second chip 116 to have the second offset OS2 with respect to the second chip 116. The third vertical portion 107c may be formed on an edge of the third chip body 103 of the third chip 102, like in the first chip 146 and the second chip 116. The chip-stacked package 200-6 may increase a degree of freedom in package design by variously forming edges of the chips 146, 116, and 102.

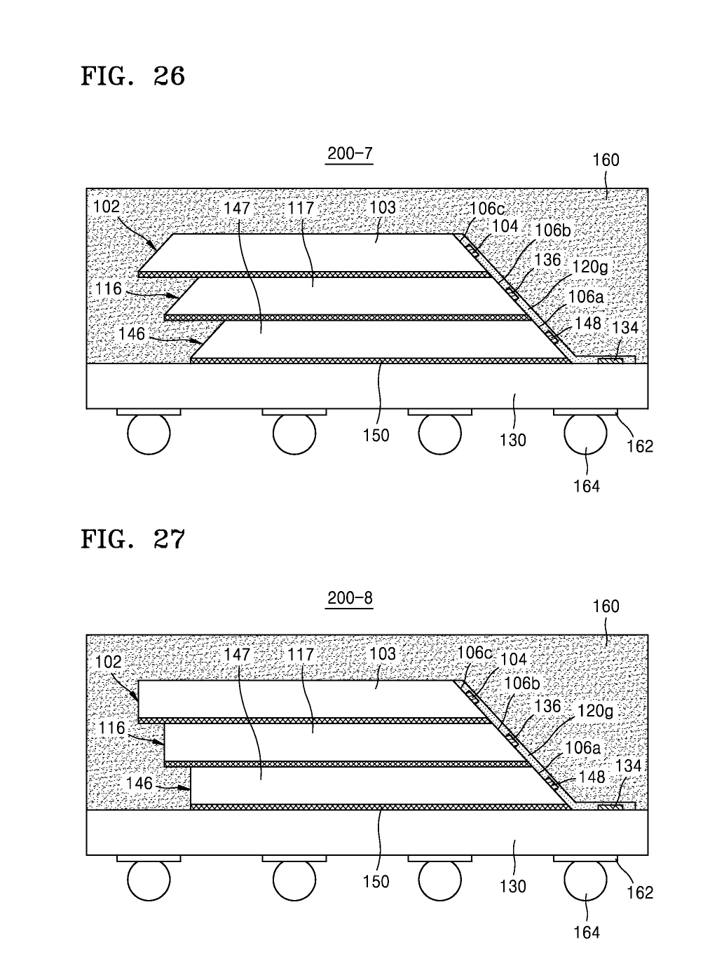

FIGS. 26 and 27 are cross-sectional views illustrating chip-stacked packages according to other example embodiments of the inventive concepts.

A chip-stacked package 200-7 may be formed by molding the chip-stacked package 200-5 of FIGS. 22 and 23 with an encapsulation member 160. A chip-stacked package 200-8 may be formed by molding the chip-stacked package 200-6 of FIGS. 24 and 25 with the encapsulation member 160.

The chip-stacked packages 200-7 and 200-8 may protect the first through third chips 146, 116, and 102 from the outside by covering the wiring substrate 130 with the encapsulation member 160. The encapsulation member 160 may be formed of, for example, an epoxy resin.

Connection pads 162 may be formed on a bottom surface of the wiring substrate 130. External connection terminals 164 to be connected to an external device may be formed on the connection pads 162. The external connection terminals 164 may be, for example, solder balls.

A method of manufacturing a chip including a sloped portion and side pads on the sloped portion and a method of manufacturing a chip-stacked package by using the chip manufacturing method will now be explained. The chip manufacturing method and the chip-stacked package manufacturing method explained below are examples, and the technical scope of the inventive concepts is not limited thereto.

FIGS. 28 through 36 are cross-sectional views for explaining a method of manufacturing a chip-stacked package, according to an example embodiment of the inventive concepts.

Referring to FIG. 28, a plurality of chips may be manufactured on a wafer 400, for example, a silicon wafer. Two chips areas 402a and 402b are illustrated in FIG. 29 for convenience of explanation. An IC may be formed on the chip areas 402a and 402b. In each of the chip areas 402a and 402b, a chip body 401 may be divided into a central portion 406 that is located at a center of the chip body 401 and an edge portion 408 that is located around an edge of the chip body 401.

Continuously, a mask layer 410 may be formed on the central portion 406 of the chip body 401 to expose the edge portion 408 of each of the chip areas 402a and 402b. The mask layer 410 may be, for example, an insulating layer.

Referring to FIG. 29, a sloped portion 412 may be formed on the edge of each of the chip areas 402a and 402b by wet-etching the edge portion 408 of the chip body 401 by using the mask layer 410 as an etching mask. When the edge portion 408 of the chip body 401 is wet-etched, the sloped portion 412 of each of the chip areas 402a and 402b may be formed due to an etching rate difference between crystal planes of the wafer 400. Because the edge portion 408 of the chip body 401 is wet-etched, the sloped portion 412 of each of the chip areas 402a and 402b may have substantially no defect. A method of forming the sloped portion 412 by using wet-etching will be explained below in detail.

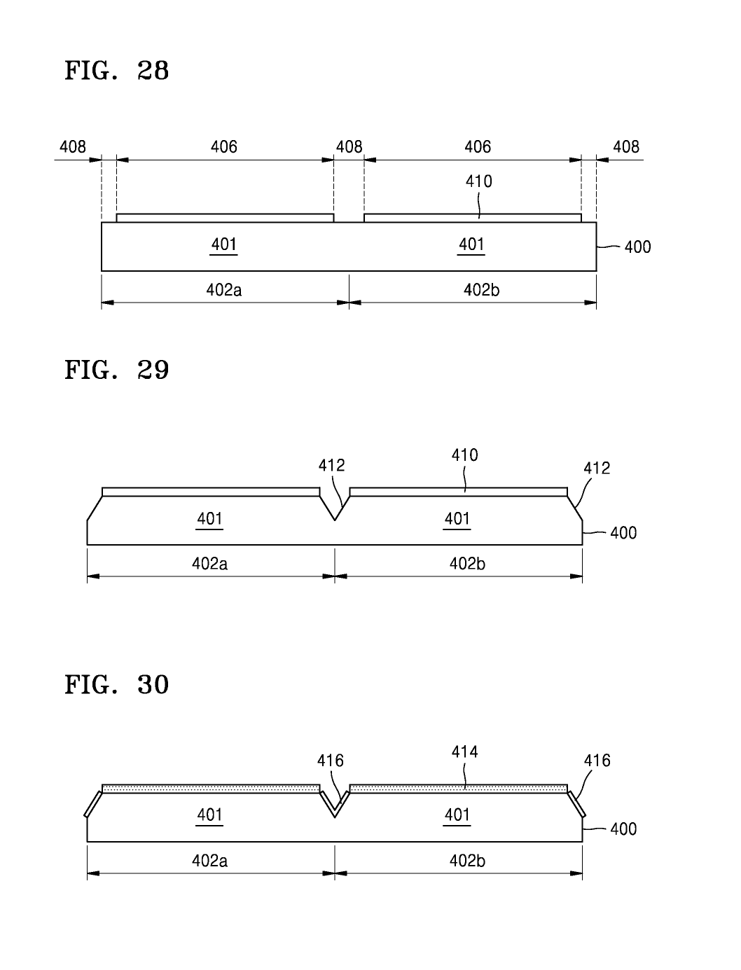

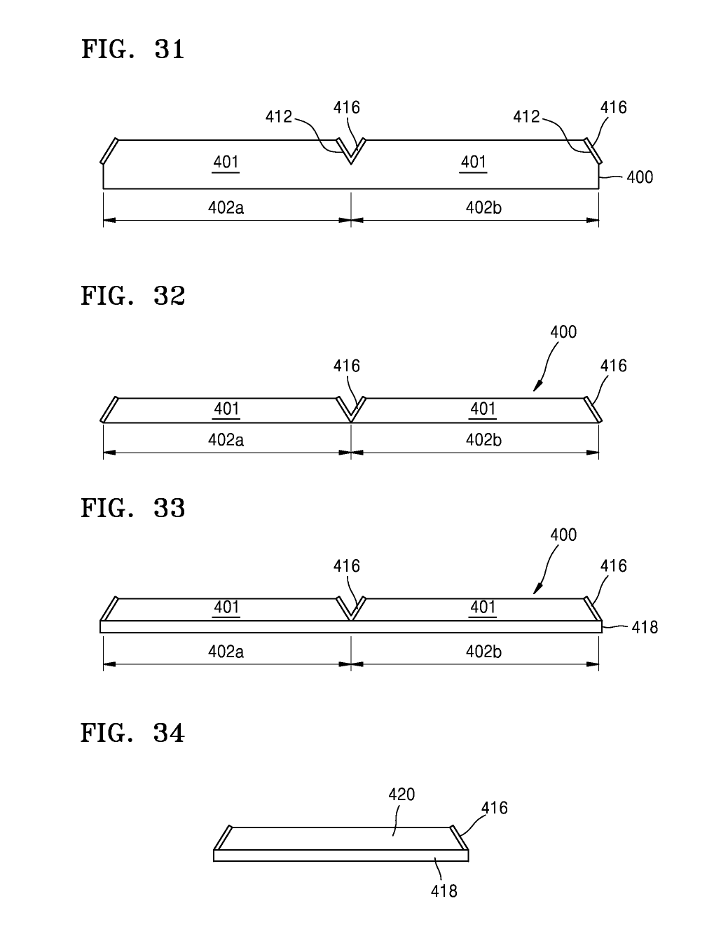

Referring to FIGS. 30 and 31, the mask layer 410 may be etched and removed as shown in FIG. 30. Next, a protective layer 414 may be formed on the central portion 406 (see FIG. 28) of the chip body 401. The protective layer 414 for protecting each of the chip areas 402a and 402b may not be formed. Side pads 416 may be formed on the sloped portion 412 of each of the chip areas 402a and 402b as shown in FIG. 32. The side pads 416 may be, for example, metal pads.

Referring to FIGS. 32 through 34, bottoms of the side pads 416 may be exposed by grinding a rear surface of the wafer 400 as shown in FIG. 32. Accordingly, the plurality of chip areas 402a and 402b each including the side pads 416 that are formed on the sloped portions 412 may be separated from each other. An adhesive tape 418 may be attached to the bottoms of the plurality of chip areas 402a and 402b as shown in FIG. 33. One chip 420 including the side pads 416 may be manufactured by cutting the adhesive tape 418 as shown in FIG. 34.

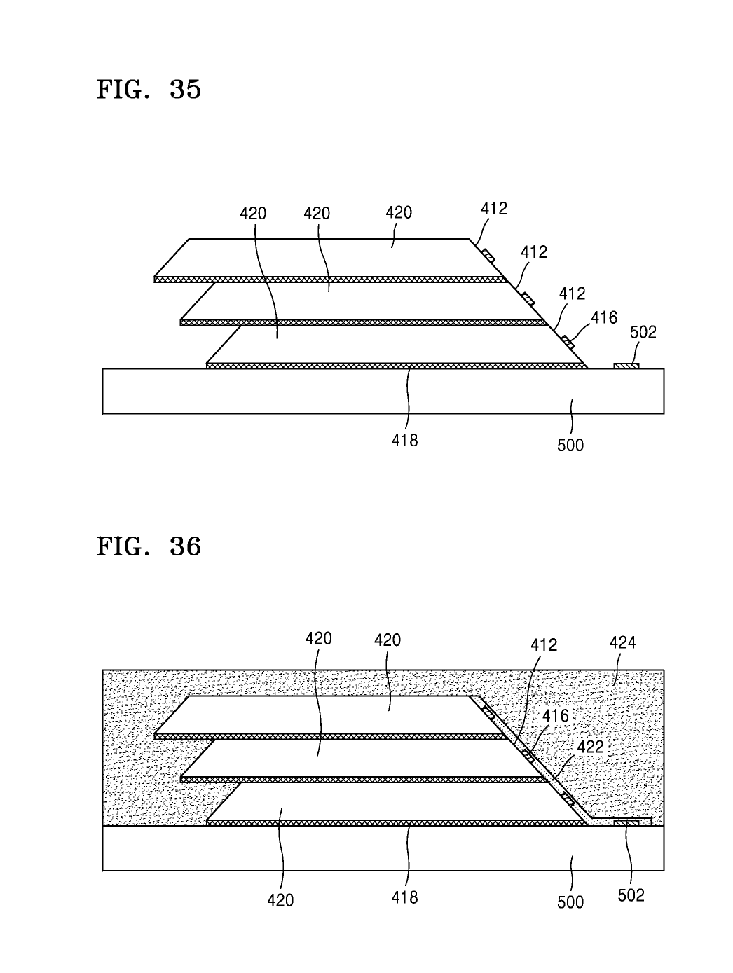

Referring to FIG. 35, a plurality of the chips 420 including the adhesive tape 418 may be aligned and stacked on a wiring substrate 500, which includes bonding pads 502. The wiring substrate 500 may be, for example, a PCB. The wiring substrate 500 may correspond to the wiring substrate 130 of FIG. 23. The bonding pads 502 may correspond to the bonding pads 134 of FIG. 23.

A method of aligning and stacking the plurality of chips 420 may be performed by allowing an upper chip to be spaced apart from an edge of a lower chip in order to have an offset, in the same manner as that described above with reference to FIGS. 22 and 23. The chips 420 may be aligned and stacked so that a plurality of sloped portions 412 are on the same plane when seen from the above. Continuously, the side pads 416 may be formed on the sloped portion 412 of each of the chips 420. The side pads 416 may be formed on, for example, a part of the sloped portion 412 as described above.

Referring to FIG. 36, conductive lines 422 may be formed to electrically connect the side pads 416 that are formed on the sloped portion 412 of the chips 420. The conductive lines 422 may be metal wires formed by, for example, printing a conductive paste. Because the plurality of sloped portions 412 are on the same plane as described above with reference to FIGS. 22 and 23, the conductive lines 422 may be easily formed by using a printing method.

The printing method may be, for example, a silk screen printing method, an inkjet printing method, or a nano-imprint method. The conductive lines 422 may be formed by printing a paste that is obtained by mixing a conductive material, for example, conductive particles (e.g., metal or carbon particles) with a solvent on the sloped portion 412 and the wiring substrate 500.

Continuously, an encapsulation member 424 may be formed on the wiring substrate 500 to protect the chips 420 from the outside impact or contaminants. The encapsulation member 424 may be formed of, for example, an epoxy resin. Continuously, connection pads and external connection terminals may be formed on a bottom surface of the wiring substrate 500 as described above with reference to FIGS. 26 and 27.

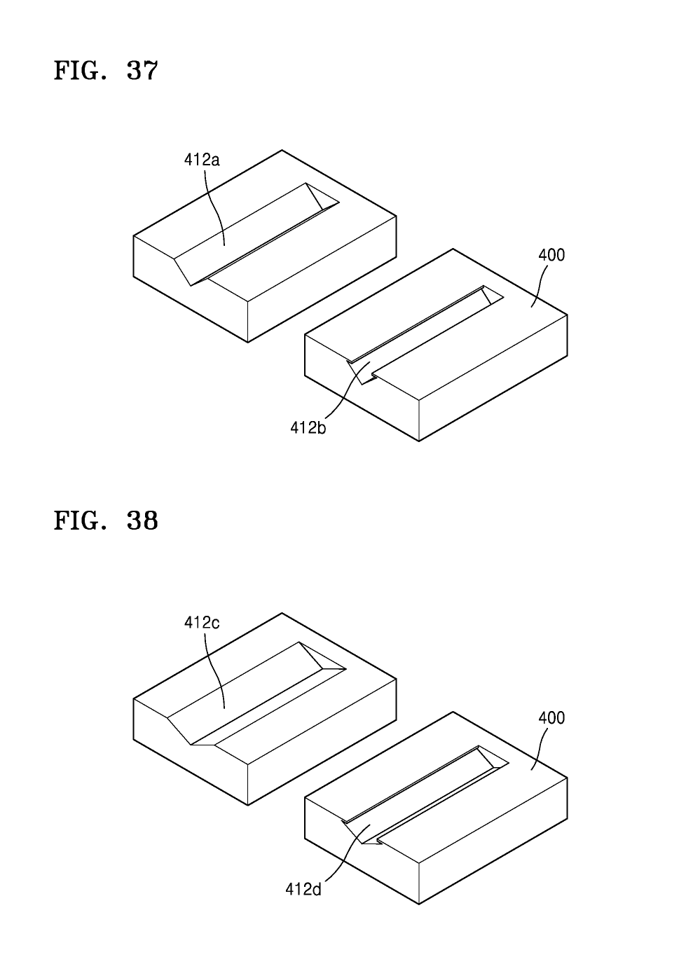

FIGS. 37 and 38 are perspective views for explaining a method of forming the sloped portion 412 of FIG. 29.

Sloped portions 412a and 412b may be formed by using an etching rate difference between crystal planes of the wafer 400, for example, a silicon wafer. That is, when the wafer 400 is a silicon wafer, the silicon wafer is etched by using, for example, a potassium hydroxide (KOH) solution, a tetra methyl ammonium hydroxide (TMAH) solution, or an ethylene diamine and pyrocatechol (EDP) solution. In this case, the sloped portions 412a and 412b may be formed by using a wet-etching rate difference between crystal planes of the silicon wafer.

For example, in FIG. 37, the wafer 400 may be a silicon wafer having a (100) plane. Each of the sloped portions 412a and 412b may be a (111) plane or a (110) plane that has a low etching rate. In FIG. 38, the wafer 400 may be a silicon wafer having a (110) plane, and each of sloped portions 412c and 412d may be a (111) plane or a (100) plane that has a low etching rate. The sloped portions 412a, 412b, 412c, and 412d may be formed as crystal plane having substantially no defect because the sloped portions 412a, 412b, 412c, and 412d are formed by wet-etching the silicon wafer.

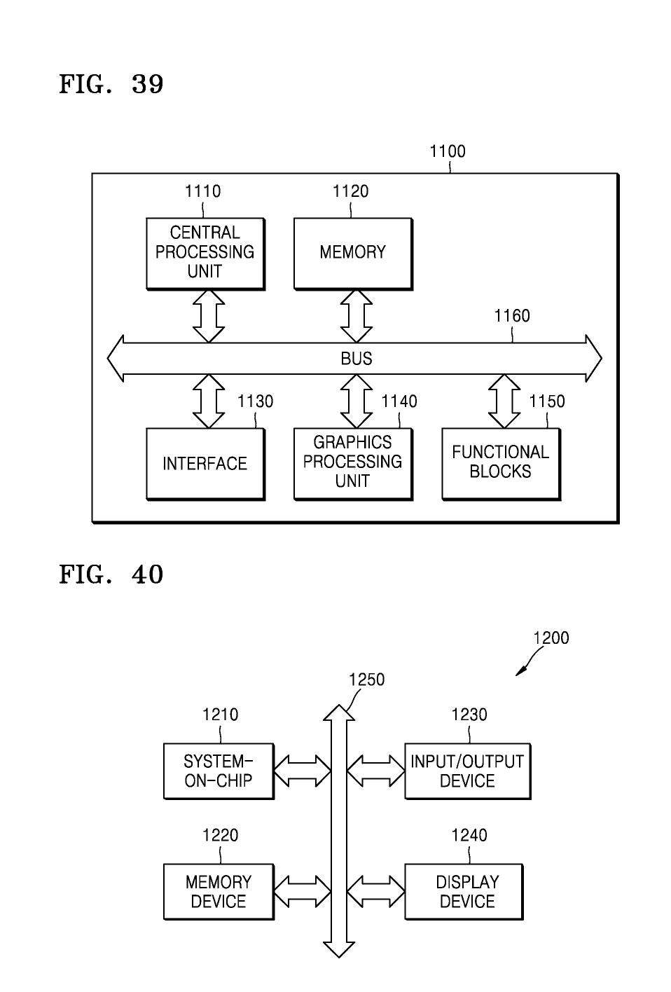

FIG. 39 is a block diagram illustrating elements of a chip-stacked package according to an example embodiment of the inventive concepts.

Examples of s chip-stacked package 1100 may include a system-on-chip (SoC). The chip-stacked package 1100 may include a central processing unit (CPU) 1110 (e.g., a controller chip), a memory 1120 (e.g., a memory chip), an interface 1130, a graphics processing unit 1140, functional blocks 1150, and a bus 1160. The CPU 1110, the memory 1120, the interface 1130, the graphics processing unit 1140, and the functional blocks 1150 may communicate with each other through the bus 1160. The CPU 1110 may control an operation of the SoC, (e.g., an operation of the chip-stacked package 1100). The CPU 1110 may include, for example, a core and an L2 cache. The CPU 1110 may include multi-cores. The multi-cores each may have the same or different functions. The multi-cores may be activated at the same time or at different times.

The memory 1120 may store a processing result of the functional blocks 1150 under the control of the CPU 1110. For example, as data that is stored in the L2 cache of the CPU 1110 is flushed, the data (e.g., the processing result) may be stored in the memory 1120. The interface 1130 may interface with external devices. For example, the interface 1130 may interface with, for example, a camera, a liquid crystal display (LCD), and a speaker. The graphics processing unit 1140 may perform graphics operations that are requested by the SoC. For example, the graphics processing unit 1140 may perform, for example, video codec or 3D graphics operations.

The functional blocks 1150 may perform various functions that are requested by the SoC. For example, when the chip-stacked package 1100 may be an application processor (AP) that is used in a mobile device, some of the functional blocks 1150 may perform a communication function. The chip-stacked package 1100 may be any of the chip-stacked packages 200 and 200-1 through 200-8 of FIGS. 9 through 27. The CPU 1110 may be any of the first through third chips 146, 116, and 102 of FIGS. 9 through 27. The memory 1120 may be any of the first through third chips 146, 116, and 102 of FIGS. 9 through 27. Because the chip-stacked package 1100 may include a main functional block having relatively high performance, for example, the CPU 1110 and/or the graphics processing unit 1140, the chip-stacked package 1100 may provide relatively high performance with respect to the same area.

FIG. 40 is a block diagram illustrating an electronic system including a chip-stacked package, according to an example embodiment of the inventive concepts.

An SoC 1210 may be mounted on the electronic system 1200. The electronic system 1200 may be, for example, a mobile device, a desktop computer, or a server. The electronic system 1200 may include a memory device 1220, an input/output device 1230, and a display device 1240. The memory device 1220, the input/output device 1230, and the display device 1240 may electrically communicate with each other through a bus 1250. The SoC 1210 may be any of the chip-stacked packages 200 and 200-1 through 200-8 of FIGS. 9 through 27. The memory device 1220 may be any of the chip-stacked packages 200 and 200-1 through 200-8 of FIGS. 9 through 27. Because the SoC 1210 including a main functional block having relatively high performance may be mounted on the electronic system 1200, the electronic system 1200 may provide relatively high performance.

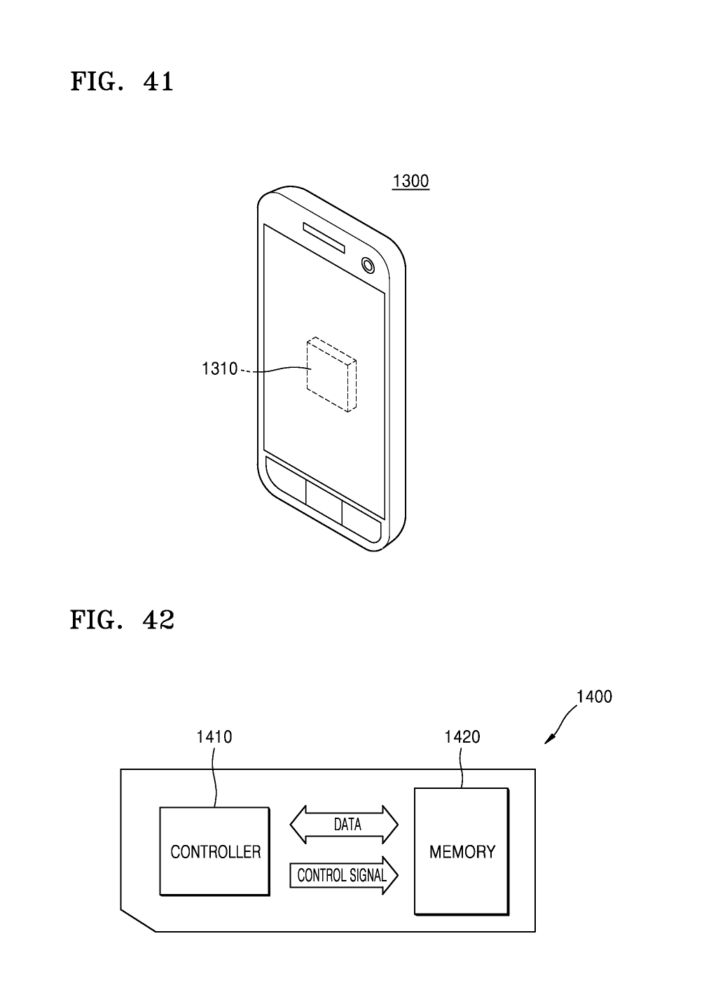

FIG. 41 is a perspective view illustrating an electronic device to which a chip-stacked package is applied, according to an example embodiment of the inventive concepts.

The electronic system 1200 of FIG. 40 may be applied to a mobile phone 1300. The mobile phone 1300 may include an SoC 1310. The SoC 1310 may be any of the chip-stacked packages 200 and 200-1 through 200-8 of FIGS. 9 through 27.

Because the mobile phone 1300 may include the SoC 1310 on which a main functional block having relatively high performance may be disposed, the mobile phone 1300 may provide relatively high performance. Because the SoC 1310 may have relatively high performance with respect to the same area, the mobile phone 1300 may provide relatively high performance with a minimized size.

Further, the electronic system 1200 may be applied to, for example, a portable notebook, an MP3 player, a navigation system, a solid-state disc (SSD), a vehicle, or a household appliance.

FIG. 42 is a block diagram illustrating elements of a card using a chip-stacked package, according to an example embodiment of the inventive concepts.

The chip-stacked packages 200 and 200-1 through 200-8 may be applied to the card 1400. Examples of a card 1400 may include, for example, a multimedia card (MMC) or a secure digital card (SD). The card 1400 may include a controller 1410 (e.g., a controller chip) and a memory 1420 (e.g., a memory chip). The memory 1420 may be, for example, a flash memory, a phase-change RAM (PRAM), or any of other nonvolatile memories.

The controller 1410 may apply a control signal to the memory 1420 and data may be exchanged between the controller 1410 and the memory 1420. Each of the controller 1410 and the memory 1420 of the card 1400 may be any of the chip-stacked packages 200 and 200-1 through 200-8 of FIGS. 9 through 27.

In a chip according to the one or more example embodiments of the inventive concepts, a sloped portion may be formed at at least one edge of a chip body and side pads may be formed on the sloped portion. Because the sloped portion is formed by wet-etching an edge of the chip, the sloped portion may be easily formed to have substantially no defect.

When a chip-stacked package is realized by using the chip including the side pads that are formed on the sloped portion, the chip-stacked package may be miniaturized and electrical conductive lines between the chip and a wiring substrate or chips may be easily formed by using a printing method.

When the chip-stacked package is realized by using the chip including the side pads that are formed on the sloped portion, the chip-stacked package may be multi-functional and have a compact size and high capacity.

While the inventive concepts have been particularly shown and described with reference to example embodiments thereof by using specific terms, the example embodiments and terms have merely been used to explain the inventive concepts and should not be construed as limiting the scope of the inventive concepts as defined by the claims. The example embodiments should be considered in a descriptive sense only and not for purposes of limitation. Therefore, the scope of the inventive concepts is defined not by the detailed description of the inventive concepts but by the appended claims, and all differences within the scope will be construed as being included in the inventive concepts.

1. A chip comprising:
a chip body including at least one sloped portion at on one or more edges of the chip body; and
a side pad on the at least one sloped portion.

2. The chip of claim 1, wherein the chip body has a quadrangular shape, and each of two facing ones from among the edges has the sloped portion.

3. The chip of claim 1, wherein the chip body has a quadrangular shape, and a respective one of the edges has the sloped portion.

4. The chip of claim 1, wherein the chip body has a quadrangular shape, and at least one from among the edges has a vertical portion, which is perpendicular to a top surface of the chip body.

5. The chip of claim 4, wherein each of two facing ones from among the edges has the sloped portion, and each of the other two facing ones from among the edges has the vertical portion.

6. (canceled)

7. The chip of claim 1, wherein the sloped portion has an inclination angle of a range between about 120° and about 150° with respect to the surface portion of the chip body.

8. (canceled)

9. The chip of claim 1, further comprising:
an insulating layer on the sloped portion, the insulating layer being around the side pad.

10. (canceled)

11. The chip of claim 1, wherein the chip body is a silicon wafer and the chip body has a top surface with a (100) plane and the sloped portion with a (111) plane or a (110) plane.

12. The chip of claim 1, wherein the chip body is a silicon wafer and the chip body have a top surface with a (110) plane and the sloped portion with a (111) plane or a (100) plane.

13. A chip-stacked package comprising:
a wiring substrate including a bonding pad on a top surface thereof;
a chip on the wiring substrate, the chip including edges and a side pad on the sloped portion, at least one of the edges having a sloped portion; and
a conductive line electrically connecting the bonding pad of the wiring substrate to the side pad of the sloped portion.

14. The chip-stacked package of claim 13, further comprising:
an insulating layer on the sloped portion, the insulating layer being around the side pad and between the conductive line and the sloped portion.

15. (canceled)

16. The chip-stacked package of claim 13, wherein each of two facing ones from among the edges has the sloped portion.

17. The chip-stacked package of claim 13, wherein each of two facing ones from among the edges has the sloped portion, and each of the other two facing ones from among the edges has a vertical portion, which is perpendicular to a top surface of the chip body.

18. The chip-stacked package of claim 13, wherein the wiring substrate includes a plurality of the bonding pads including the bonding pad, the chip includes a plurality of the side pads including the side pad, the plurality of the side pads corresponding to the plurality of bonding pads, respectively, and at least some of the plurality of bonding pads are connected to at least some of the plurality of side pads, respectively, through a plurality of the conductive lines including the conductive line.

19. A chip-stacked package comprising:
a first chip including a first chip body, the first chip body including a first sloped portion at at least one edge of the first chip body and a first side pad on the first sloped portion;
a second chip on the first chip, the second chip including a second chip body, the second chip body including a second sloped portion on at least one edge of the second chip body and a second side pad on the second sloped portion; and
a conductive line on the first sloped portion and the second sloped portion, the conductive line electrically connecting the first side pad of the first chip and the second side pad of the second chip.

20. The chip-stacked package of claim 19, wherein the first sloped portion and the second sloped portion are configured to be on a same plane when seen from above.

21. (canceled)

22. The chip-stacked package of claim 19, further comprising:
a plurality of the first side pads including the first side pad;
a plurality of the second side pads including a second side pad and corresponding to the plurality of first side pads, respectively; and
at least some of the plurality of first side pads are connected to at least some of the plurality of second side pads, respectively, through the plurality of the conductive lines including the conductive line.

23. The chip-stacked package of claim 19, wherein a size of the second chip is less than a size of the first chip, and the second chip is stacked on the first chip such that the second chip is entirely within a boundary of the first chip when seen from above.

24. The chip-stacked package of claim 19, wherein a size of the second chip is same as a size of the first chip, and the second chip is stacked on the first chip to have an offset with respect to the first chip.

25.-39. (canceled)

40. A chip-stacked package comprising:
a wiring substrate having bonding pads thereon;
a first chip on the wiring substrate and including a first chip body, the first chip body including
a first planar top surface, and
first edges surrounding the first planar top surface, at least one of the first edges being a first sloped edge;
first side pads on the first sloped edge; and
first conductive lines electrically connecting the bonding pads to the first side pads, respectively.

41. The chip-stacked package of claim 40, further comprising:
a second chip on the first chip and including a second chip body, the second chip body including
a second planar top surface, and
second edges surrounding the second planar top surface, at least one of the second edges being a second sloped edge;
second side pads on the second sloped edge; and
second conductive lines electrically connecting the bonding pads to the second side pads, respectively.

42. The chip-stacked package of claim 41, wherein the second conductive line electrically connects the bonding pads to the second side pads via the first side pads.

43. The chip-stacked package of claim 41, wherein the first sloped edge and the second sloped edge are one a same plane when seen from above.

44. The chip-stacked package of claim 40, further comprising:
a second chip on the first chip and including a second chip body, the second chip body including a second planar top surface and vertical edges surrounding the second planar top surface, the vertical edges being perpendicular to the second top planar surface;
surface pads on the second planar top surface sloped edge; and
second conductive lines electrically connecting the bonding pads to the surface pads, respectively.

45. The chip-stacked package of claim 44, wherein the second conductive lines
electrically connect the bonding pads to the surface pads via the first side pads.

46. The chip-stacked package of claim 40, wherein the first chip body has a quadrangular shape, and at least one of the first edges is a vertical edge, which is perpendicular to the first planar top surface.

47. The chip of claim 40, wherein the first chip body is a silicon wafer, and when the first planar top surface has a (100) crystal plane and the first sloped edge has a (111) crystal plane or a (110) plane, and when the first planar top surface has a (110) crystal plane and the first sloped edge has a (111) crystal plane or a (100) plane.
